(19) United States
(12) Patent Application Publication
(10) Pub. No.: US 2025/0120112 A1
(43) Pub. Date: Apr. 10, 2025

(54) SEMICONDUCTOR STRUCTURE FOR GATE ALL AROUND NANOSHEET DEVICE

(71) Applicant: HUAWEI TECHNOLOGIES CO., LTD., Shenzhen (CN)

(72) Inventors: Krishna Kumar Bhuwalka, Leuven (BE); Yijian CHEN, Shenzhen (CN)

(21) Appl. No.: 18/914,098

(22) Filed: Oct. 12, 2024

Related U.S. Application Data
(63) Continuation of application No. PCT/CN2022/086579, filed on Apr. 13, 2022.

(51) Int. Cl. H10D 30/00; H10D 30/01

(52) U.S. Cl. CPC H10D 30/508; H10D 30/0195

(57) ABSTRACT

A semiconductor structure and fabrication method is provided for gate all around (GAA) nanosheet devices. The semiconductor structure comprises a substrate, a gate stack on the substrate with a plurality of gate regions and silicon-based channel regions alternatingly arranged one on the other. A length of the gate regions is smaller than a length of the channel regions. Thus, pockets are formed on a side of the gate stack, each pocket being arranged next to one gate region and between the two channel regions adjacent to the gate region. Further, a silicon-based first contact region extends in a distance to the side of the gate stack, and a silicon-based filler material is arranged between the first contact region and the first side of the gate stack and in each first pocket.

### CROSS-REFERENCE TO RELATED APPLICATIONS

This application is a continuation of International Application No. PCT/CN2022/086579, filed on Apr. 13, 2022, the disclosure of which is hereby incorporated by reference in its entirety.

### TECHNICAL FIELD

Embodiments of the present disclosure relate to a gate all around (GAA) nanosheet device and similar devices. For such kinds of devices, embodiments of this disclosure provide a suitable semiconductor structure, and a method for fabricating the semiconductor structure. The GAA nanosheet device may be fabricated based on the semiconductor structure, for example, by using the method for fabricating the semiconductor structure. The GAA nanosheet device may also include the semiconductor structure.

### BACKGROUND

GAA nanosheet devices are seen as promising device architecture, which may allow further scaling of complementary metal oxide semiconductor (CMOS) devices beyond FinFET limitations.

One challenge of fabricating a GAA nanosheet device is to reduce parasitic capacitances between gates regions and source/drain regions in the final device. This may, for example, be achieved by processing inner spacers between the gate regions and the source/drain regions during the fabrication of the device. Various exemplary schemes have been proposed to make such inner spacers. However, the processing of the inner spacers results in process complexity and device performance risks.

In addition, also various GAA nanosheet devices without such inner spacers have been proposed. However, these dese device architectures have the drawback of a relatively large gate length, since the gate length is determined by the etching of the epitaxially grown nanosheets into a gate stack.

### SUMMARY

This present disclosure aims to overcome the above-mentioned drawbacks. Embodiments of the disclosure provide a semiconductor structure for a GAA nanosheet device, or a similar device, which allows reducing the parasitic capacitances without having inner spacers, and further provide shorter gate lengths and an accurate control over the gate length. The method for fabricating the semiconductor structure is of low complexity.

Embodiments of the disclosure provide controlling the (inner) gate length by a selective etch process, but do not require any inner spacers.

A first aspect of this disclosure provides a semiconductor structure comprising: a substrate; a gate stack arranged on the substrate, the gate stack including a plurality of gate regions and a plurality of silicon-based channel regions, which are alternatingly arranged one on the other along a first direction, wherein a length of the gate regions into a second direction, which is perpendicular to the first direction, is smaller than a length of the channel regions, wherein a plurality of first pockets are formed on a first side of the gate stack, each first pocket being arranged next to one gate region and between the two channel regions adjacent to the gate region; a silicon-based first contact region extending along the first direction in a distance to the first side of the gate stack; and a silicon-based filler material arranged between the first contact region and the first side of the gate stack and in each first pocket.

The first pockets, which are filled with the filler material, define the length of the gate regions—and thus the above-mentioned gate length in the final device—to the first side of the gate stack. In particular, the first pockets reduce the gate length and create a distance between the gate regions and the first contact region. The gate capacitance can be reduced in this way. Further, the first pockets may beneficially provide a high-selectivity for the removal of sacrificial semiconductor layers during the fabrication process of the semiconductor structure (explained later in detail).

In a possible implementation of the first aspect, the semiconductor structure further comprises: a silicon-based second contact region extending along the first direction in a distance to a second side of the gate stack, which is opposite the first side of the gate stack; wherein a plurality of second pockets are formed on the second side of the gate stack, each second pocket being arranged next to one gate region and between the two channel regions adjacent to the gate region; and the filler material is arranged between the second contact region and the second side of the gate stack and in each second pocket.

The second pockets, which are filled with the same filler material, define the length of the gate regions to the second side of the gate stack, and else provide similar advantages as described above for the first pockets.

In a possible implementation of the first aspect, the semiconductor structure is designed for a GAA nanosheet device, wherein: the plurality of channel regions are formed by a plurality of nanosheets; and the plurality of gate regions are connected to each other to form an integral gate structure that surrounds the gate stack in the first direction and in a third direction, which is perpendicular to the first and the second direction.

The semiconductor structure thus allows fabricating an improved GAA nanosheet or similar device, without the drawbacks of the conventional approaches

In a possible implementation of the first aspect, the filler material comprises undoped silicon, or doped silicon, or undoped silicon germanium, or doped silicon germanium.

In a possible implementation of the first aspect, the first contact region and/or the second contact region comprises doped silicon or doped silicon germanium or a combination of both.

For instance, the semiconductor structure may comprise silicon first and/or second pockets and silicon first and/or second regions, in particular, for fabricating an N-FET GAA nanosheet device. The semiconductor structure may also comprise silicon first and/or second pockets and silicon germanium first and/or second regions, in particular, for fabricating a P-FET GAA nanosheet device.

In a possible implementation of the first aspect, a doping concentration is higher in the first contact region and/or in the second contact region than in the filler material.

In a possible implementation of the first aspect, a first region of the gate stack in the first direction is a gate region, which is provided on the substrate, and a last region of the gate stack in the first direction is another gate region.

Thus, each channel region is advantageously sandwiched by two gate regions.

In a possible implementation of the first aspect, each gate region comprises a metallic region and a dielectric region configured to electrically isolate the metallic region from the channel regions adjacent to the gate region.

A second aspect of this disclosure provides a method for fabricating a semiconductor structure according to the first aspect or any of its implementation forms, wherein the method comprises: forming an interim gate stack on the substrate, the interim gate stack including a plurality of sacrificial semiconductor (e.g., SiGe or Ge) regions and the plurality of silicon-based (e.g. SiGe or Ge based) channel regions alternatingly arranged one on the other along the first direction; processing the sacrificial semiconductor regions so that a length of the sacrificial semiconductor regions into the second direction becomes smaller than a length of the channel regions, wherein the plurality of first pockets are formed on the first side of the interim gate stack, each first pocket being arranged next to one sacrificial semiconductor region and between the two channel regions adjacent to the sacrificial semiconductor region; depositing the filler material such that the filler material surrounds the processed interim gate stack and fills the first pockets; forming the first contact region in the distance to the first side of the interim gate stack; removing the sacrificial semiconductor regions; and forming the gate regions at the locations where the sacrificial semiconductor regions were removed, to form the gate stack.

The method of the second aspect provides a low-complexity process for fabricating the semiconductor structure, for example, the one of the first aspect. The forming of the first pockets can be performed by selective removal of parts of the sacrificial semiconductor regions arranged on the first side of the interim gate stack. This supports a precise control over the gate length to the first side of the gate stack. The filling material allows completely removing the sacrificial semiconductor regions with a high selectivity and accuracy, which also supports the precise control over the gate length to the first side of the gate stack.

In a possible implementation of the second aspect, wherein the plurality of second pockets are formed on the second side of the interim gate stack, each second pocket being arranged next to one sacrificial semiconductor region and between the two channel regions adjacent to the gate region; wherein the filler material fills the second pockets; and the method further comprises, before removing the sacrificial semiconductor regions, forming the second contact region in the distance to the second side of the interim gate stack.

The forming of the second pockets can be performed by selective removal of parts of the sacrificial semiconductor regions on the second side of the interim gate stack. This supports precise control over the gate length to the second side of the gate stack. The filling material allows completely removing the sacrificial semiconductor regions with a high selectivity and accuracy, which also supports the precise control over the gate length to the second side of the gate stack.

In a possible implementation of the second aspect, the first contact region and the second contact region are formed simultaneously.

The first and second pockets can also be formed simultaneously.

In a possible implementation of the second aspect, the interim gate stack is formed by epitaxial growth on the substrate.

In a possible implementation of the second aspect, the method further comprises, after depositing the filler material: forming a first trench and/or a second trench along the first direction into the filler material; and forming the first contact region and/or the second contact region in, respectively, the first trench and/or the second trench.

In a possible implementation of the second aspect, the processing of the sacrificial semiconductor regions comprises selective etching of a material of the sacrificial semiconductor regions; and/or the removal of the sacrificial semiconductor regions comprises selective etching of the material of the sacrificial semiconductor regions.

This provides a precise control over the size of the first pockets and/or second pockets, and thus the respective gate lengths.

In a possible implementation of the second aspect, the material of the sacrificial semiconductor regions comprises silicon germanium.

In a further possible implementation, the sacrificial semiconductor regions may have different material compositions. For instance, the sacrificial semiconductor regions may comprise multiple SiGe layers with different Ge concentrations. This changes the etch rate of the SiGe layers and provides a better gate control.

A third aspect of this disclosure provides a GAA nanosheet device, wherein the GAA nanosheet device comprises the semiconductor structure of the first aspect or any of its implementation forms, or is fabricated using the method of the second aspect or any of its implementation forms, or is fabricated based on the semiconductor structure of the first aspect and any of its implementation forms.

Overall, embodiments of this disclosure provides a selective removal process of sacrificial semiconductor regions, in order to make the pockets and increase the distance to the contact regions, but dielectric inner spacers are not required to reduce the parasitic capacitances.

### BRIEF DESCRIPTION OF DRAWINGS

The above described aspects and implementation forms will be explained in the following description of specific embodiments in relation to the enclosed drawings, in which

FIG. 1 shows a semiconductor structure according to this disclosure.

FIG. 2 shows a semiconductor structure according to this disclosure.

FIG. 3 shows a flow-diagram of a method according to this disclosure.

FIG. 4 shows a first step of a method according to this disclosure.

FIG. 5 shows a further step of the method with regard to FIG. 4.

FIG. 6 shows a further step of the method with regard to FIG. 4.

FIG. 7 shows a further step of the method with regard to FIG. 4.

FIG. 8 shows a further step of the method with regard to FIG. 4.

### DETAILED DESCRIPTION OF EMBODIMENTS

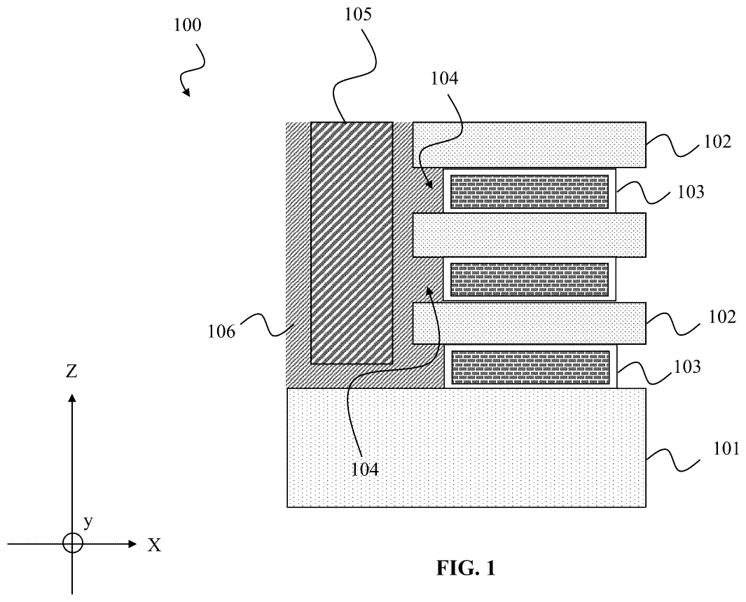

FIG. 1 shows a semiconductor structure 100 according to this disclosure. The semiconductor structure 100 may be designed for a GAA nanosheet device or for a similar device. That is, based on the semiconductor structure 100, the GAA nanosheet device may be fabricated. The GAA nanosheet device may also comprise the semiconductor structure 100 or at least parts of the semiconductor structure 100 (if the semiconductor structure 100 is further processed to obtain the final GAA nanosheet device).

The semiconductor structure 100 comprises a substrate 101, which may be silicon-based and/or may be a wafer, like a wafer that is provided with a silicon-based substrate layer.

The semiconductor structure 100 further comprises a gate stack, which is arranged on the substrate 101. For instance, the gate stack may be epitaxially grown on the substrate 101. The gate stack includes a plurality of gate regions 103 and a plurality of silicon-based channel regions 102, which are alternatingly arranged one on the other along a first direction (along the Z-axis as indicated). That is, the gate regions 103 and channel regions 102 are stacked to form the gate stack. The silicon-based channels regions 102 may be silicon channel regions 102. The gate regions 103 may be metallic regions with a surrounding dielectric region (as indicated by the different shadings in FIG. 1) to electrically isolate the metallic region from the channel regions 102, which are adjacent to the gate region 103. The metal may be a combination of conductors defining work-function like TiN and TaN, or the like. The dielectric regions may be made of a high-k material or an oxide or the like or a combination of both or more including a work-function shifting dipole.

As can be seen in FIG. 1, a length of the gate regions 103 into a second direction (along the X-axis as indicated), which is perpendicular to the first direction (Z-axis), is smaller than a length of the channel regions 102. Notably, the X-Axis, Z-Axis and Y-Axis as indicated in the figures may define a coordinate system. Due to the smaller length of the gate regions 103, a plurality of first pockets 104 are formed on a first side of the gate stack. Each first pocket 104 is arranged next to one of the gate regions 103 and between the two channel regions 102 adjacent to this one of the gate regions 103 (namely, the channel region above this gate region 103 and/or the channel region below this gate region 103, e.g., the channel regions 102 sandwiching this gate region 103).

The semiconductor structure 100 further comprises a silicon-based first contact region 105 extending along the first direction (Z-axis) in a distance to the first side of the gate stack. That is, there is a gap between the first contact region 105 and the gate stack in the second direction. The first contact region 105 may be used for a source/drain contact to the channel regions 102. The first contact region 105 may comprise doped silicon or doped silicon germanium.

The semiconductor structure 100 further comprises a silicon-based filler material 106, which is arranged between the first contact region 105 and the first side of the gate stack and is arranged in each one of the first pockets 104. The filler material 106 may comprise undoped silicon, or doped silicon, or undoped silicon germanium, or doped silicon germanium. Beneficially, a doping concentration in the first contact region 105 is higher than a doping concentration in the filler material 106. The filler material 106 and the first pockets 104 may be the same and may be grown at the same time.

In case that the semiconductor structure 100 is designed for a GAA nanosheet device, the plurality of channel regions 102 may be formed by a plurality of nanosheets. That is, each channel region 102 may be formed by a nanosheet. Further, the plurality of gate regions 103 are all connected to each other in this case, in order to form an integral gate structure that surrounds the gate stack in the first direction (Z-axis) and in a third direction (in the Y-axis), which is perpendicular to the first and the second direction (Z-axis and X-axis).

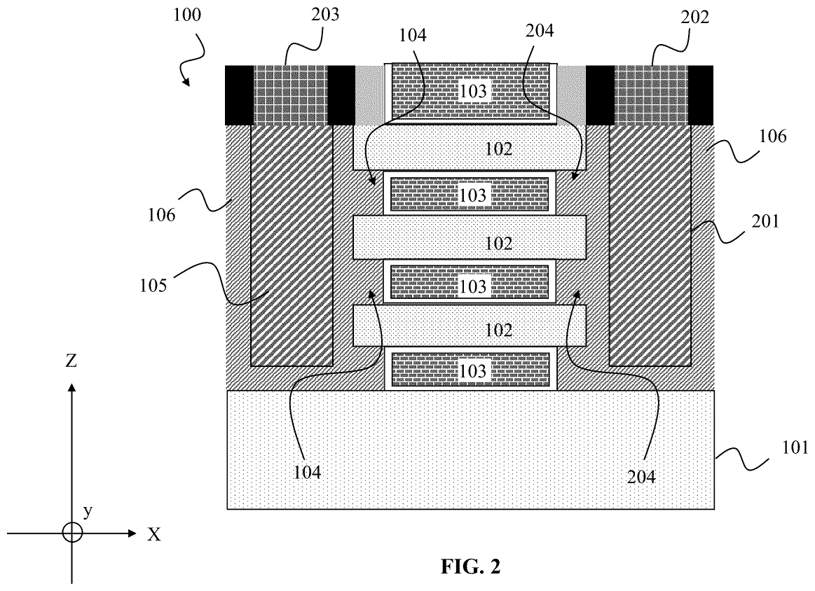

FIG. 2 shows a semiconductor structure 100 according to this disclosure, which builds on the semiconductor structure 100 of FIG. 1. Same elements in FIG. 1 and FIG. 2 are labelled with the same reference signs and may be implemented likewise.

The semiconductor structure 100 of FIG. 2 includes, in addition to what is comprised by the semiconductor structure 100 of FIG. 1, a silicon-based second contact region 201 extending along the first direction (Z-axis) in a distance to a second side of the gate stack. The second side of the gate stack is opposite to the first side of the gate stack. That is, the first side and the second side of the gate stack are opposite sides of the gate stack in the second direction (X-axis). Accordingly, there is a gap between the second contact region 201 and the gate stack in the second direction. The second contact region 201 may be used for a source/drain contact to the channel regions 102. The second contact region 201 may comprise doped silicon or doped silicon germanium.

Further, similar to the first pockets 104, a plurality of second pockets 204 are formed on the second side of the gate stack. Each second pocket 204 is arranged next to one of the gate regions 103 and between the two channel regions 102 adjacent to the one of the gate regions 103. That is, each second pocket 204 is between the channel regions 102 sandwiching this one of the gate regions 103. The filler material 106 is arranged between the second contact region 201 and the second side of the gate stack and also in each second pocket 204. Beneficially, a doping concentration in the second contact region 201 is higher than a doping concentration in the filler material 106.

FIG. 2 shows also that a first region of the gate stack in the first direction starting from the substrate 101 is a gate region 103 (to form an “inner gate region”), which is provided on the substrate 101, and that also a last region of the gate stack in the first direction (Z-axis) is another gate region 103 (to form a “top gate region”).

Further, metal contacts 203 and 202 can be formed on the first contact region 105 and the second contact region 201, respectively. The metal contacts 203 and 202 may respectively be surrounded by one or more dielectric materials, in order to be isolated from the top gate region 103 of the gate stack.

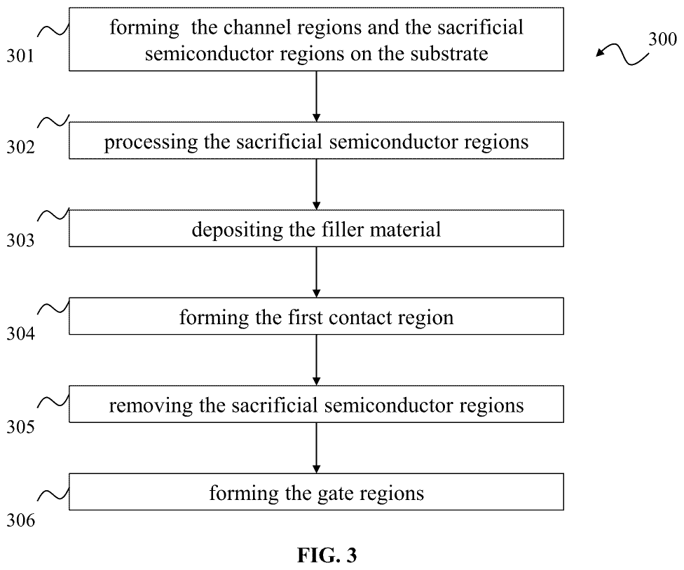

FIG. 3 shows a general method 300 for fabricating the semiconductor structure 100 shown in FIG. 1 or FIG. 2. In particular, the method 100 leads to the semiconductor structure 100 shown in FIG. 1, but it may also be used to fabricate the semiconductor structure 100 shown in FIG. 2.

The method 300 comprises a step 301 of forming a series of channel regions 102 (e.g., semiconductor layers comprising Si or SiGe) and sacrificial semiconductor regions (e.g., semiconductor layers comprising SiGe or Si, later replaced by the gate regions 103) on the substrate 101. The plurality of sacrificial semiconductor regions and the plurality of silicon-based channel regions 102 are alternatingly arranged one on the other along the first direction (Z-axis), and together form a so-called “interim gate stack” on the substrate 101. Further, the method 300 comprises a step 302 of processing the sacrificial semiconductor regions so that a length of the sacrificial semiconductor regions into the second direction (X-axis) becomes smaller than a length of the channel regions 102. In this step 302, the plurality of first pockets 104 are formed on the first side of the interim gate stack, each first pocket 104 being arranged next to one sacrificial semiconductor region and between the two channel regions 102 adjacent to the sacrificial semiconductor region.

Selective removal of the sacrificial regions to form second pockets on the other side of the interim gate stack may be done simultaneously. Also, the second pockets may be formed simultaneously to the first pockets.

The method 300 further comprises a step 303 of depositing the filler material 106 such that the filler material 106 surrounds the processed interim gate stack and fills the first pockets 104, and a step 304 of forming the first contact region 105 in the distance to the first side of the interim gate stack.

Then, the method 300 comprises a step 305 of removing the sacrificial semiconductor regions, and a step 306 of forming the gate regions at the locations where the sacrificial semiconductor regions were removed, to form the gate stack.

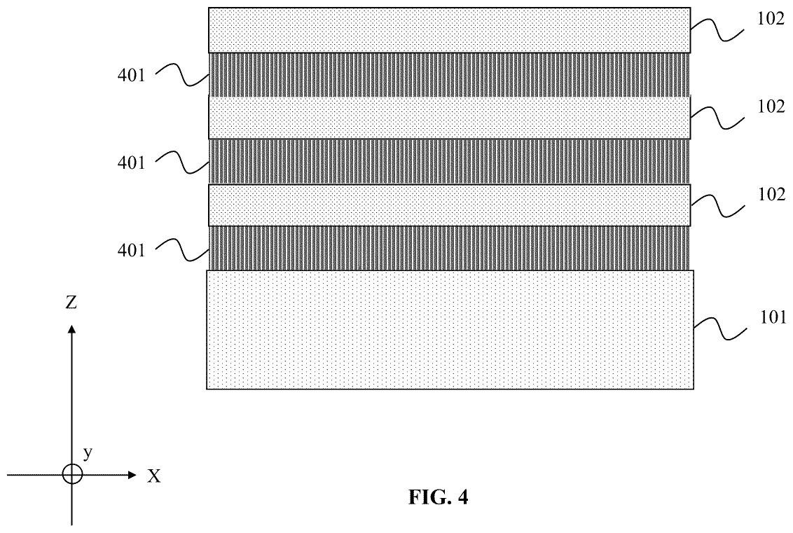

FIGS. 4-8 show an exemplary method 300 according to this disclosure, which builds on the general method 300 shown in FIG. 3. Same elements in the FIGS. 4-8 and in FIG. 1 and FIG. 2 are labelled with the same reference signs and may be implemented likewise.

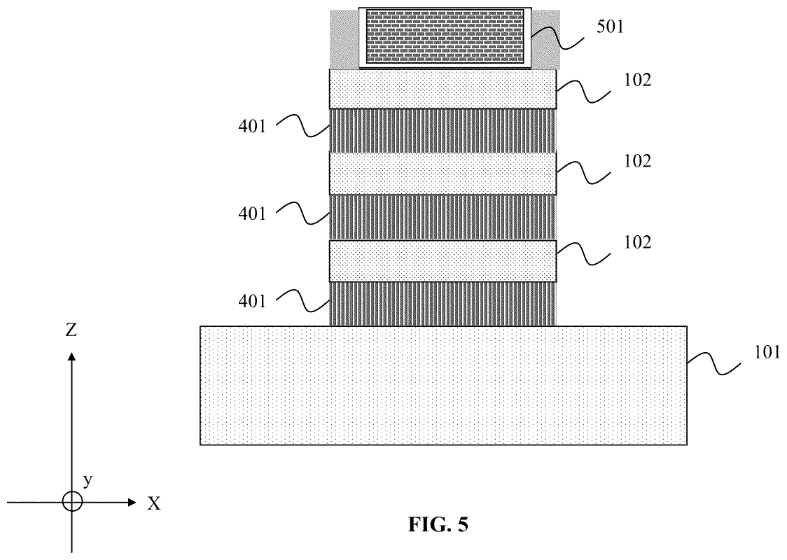

FIG. 4 and FIG. 5 shows the first step 301 of the method 300, in particular, the formation of the interim gate stack. The interim gate stack includes the plurality of sacrificial semiconductor regions 401 (e.g., silicon germanium regions) and the plurality of silicon-based channel regions 102 (e.g., silicon regions), which are alternatingly arranged one above the other along the first direction (Z-axis). As shown in FIG. 4, these regions/layers 102 and 401 may be formed by epitaxial growth on the substrate 101 (to form an epi stack). As shown in FIG. 5, the epi stack may then be etched, and may thereby be recessed in the second direction (made more narrow in the X-direction) to result in the interim gate stack. A dummy gate region 501 may also be formed as the last region of the interim gate stack in the first direction (Z-axis).

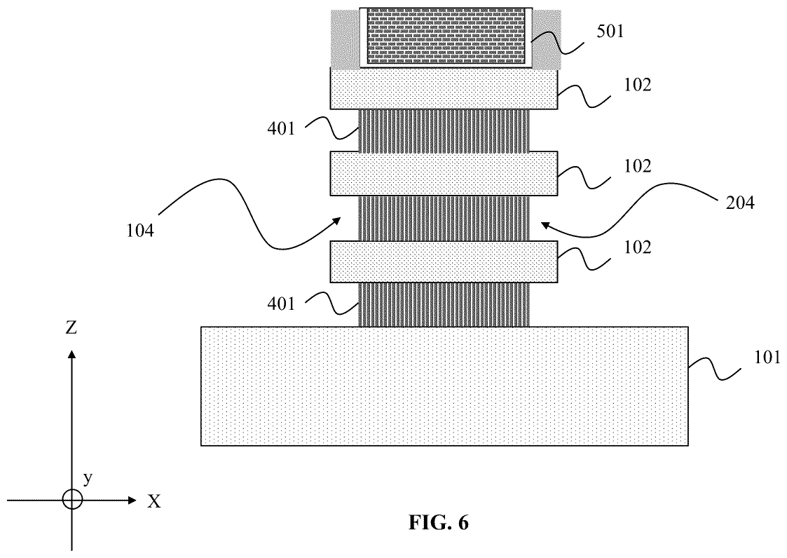

FIG. 6 shows the step 302 of processing the sacrificial semiconductor regions 401, so that a length of the sacrificial semiconductor regions 401 into the second direction (X) becomes smaller than a length of the channel regions 102. For example, this step 302 may comprise a selective etching of the material of the sacrificial semiconductor regions 401. A part of each sacrificial semiconductor region 401 may be laterally removed. For instance, silicon germanium may be selectively etched. In this way, the first pockets 104 and the second pockets 204 are formed.

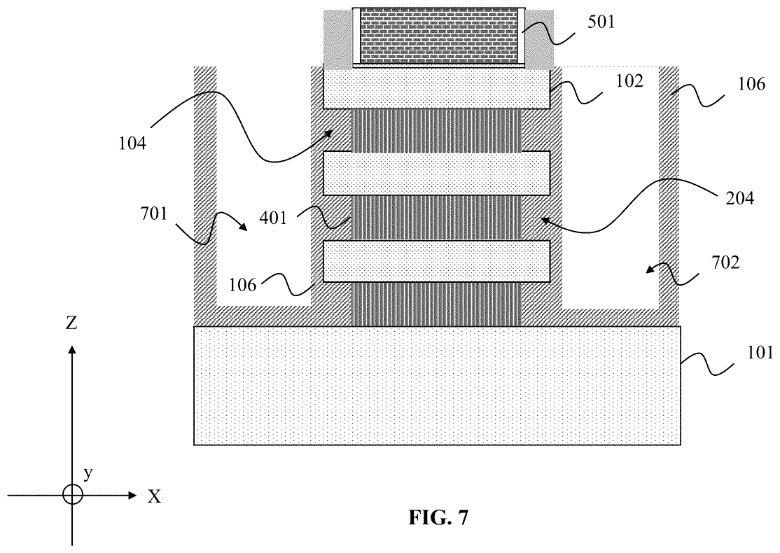

FIG. 7 shows the step 303 of depositing the filler material 106. The filler material 106 surrounds the processed interim gate stack and fills the first pockets 104 and the second pockets 204. Further, FIG. 7 shows a step of forming a first trench 701 and a second trench 702 along the first direction (Z-axis) into the filler material 106.

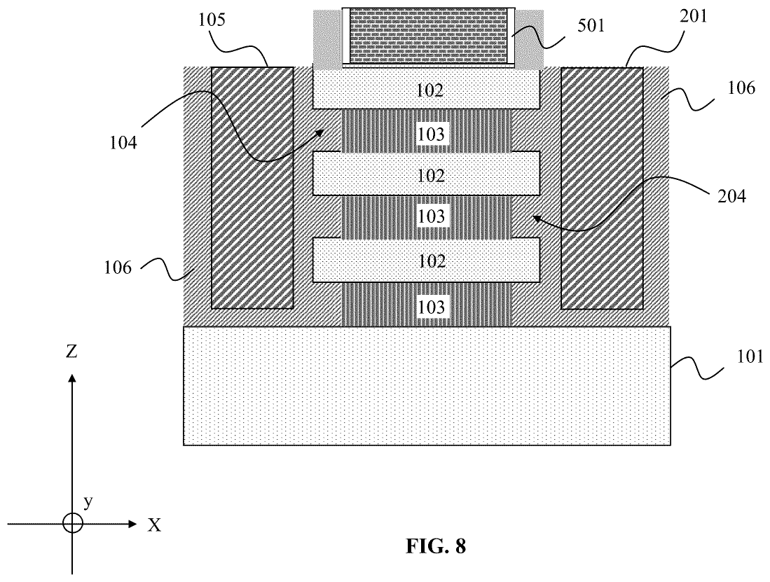

FIG. 8 shows the step 305 of forming the first contact region 105 in a distance to the first side of the gate stack. FIG. 8 also shows that simultaneously the second contact region 201 is formed in a distance to the second side of the interim gate stack. In particular, the first contact region 105 is formed in the first trench 701, and the second contact region 201 is formed in the second trench 702. In case that an N-FET is processed, silicon may be deposited to form the first contact region 105 and the second contact region 201. In case that a P-FET is processed, silicon germanium may be deposited to form the first contact region 105 and the second contact region 201.

When etching the epi layers shown in FIG. 4, in order to form the interim gate stack shown in FIG. 5, it may happen in some cases that the etch leads to an (upward) tapered interim gate stack, which may further lead to tapering gate lengths and thus asymmetric gate control. Also the channel lengths may be tapering in this case, but this may have less impact. As a solution to this potential issue—particularly if no such tapering is desired—the sacrificial layers 401 can all be silicon germanium layers, and the germanium fraction of the silicon germanium sacrificial layers 401 can be increased from the top to the bottom (i.e., a higher germanium fraction can be used, the closer the sacrificial semiconductor region 401 is to the substrate 101). This may result in an increase of the lateral etch rates of the sacrificial semiconductor region 401 during the selective etching of the sacrificial layers 401. In particular, sacrificial layers 401 with a higher germanium fraction may have a higher etch rate.

The present disclosure has been described in conjunction with various embodiments as examples as well as implementations. However, other variations can be understood and effected by those persons skilled in the art and practicing the claimed matter, from the studies of the drawings, this disclosure and the independent claims. In the claims as well as in the description the word “comprising” does not exclude other elements or steps and the indefinite article “a” or “an” does not exclude a plurality. A single element or other unit may fulfill the functions of several entities or items recited in the claims. The mere fact that certain measures are recited in the mutual different dependent claims does not indicate that a combination of these measures cannot be used in an advantageous implementation.

1. A semiconductor structure comprising:
a substrate;
a gate stack arranged on the substrate;
a silicon-based first contact region extending along the first direction (Z) at a distance from the first side of the gate stack;
a silicon-based filler material arranged between the silicon-based first contact region and the first side of the gate stack and in each first pocket;
wherein the gate stack includes a plurality of gate regions and a plurality of silicon-based channel regions, which are alternatingly arranged along a first direction (Z).
wherein a length of the gate regions into a second direction (X), which is perpendicular to the first direction (Z), is smaller than a length of the silicon-based channel regions, and
wherein a plurality of first pockets are formed on the first side of the gate stack, and each first pocket is arranged next to one gate region and between two of the silicon-based channel regions adjacent to the gate region.

2. The semiconductor structure according to claim 1, further comprising:
a silicon-based second contact region extending along the first direction (Z) at a distance from a second side of the gate stack, which is opposite the first side of the gate stack;
wherein a plurality of second pockets are formed on the second side of the gate stack, each second pocket is arranged next to one gate region and between the two channel regions adjacent to the gate region; and
wherein the filler material is arranged between the second contact region and the second side of the gate stack and in each second pocket.

3. The semiconductor structure according to claim 1, wherein the semiconductor structure is designed for a gate all around (GAA) nanosheet device, and wherein:
the plurality of channel regions are formed by a plurality of nanosheets; and
the plurality of gate regions are connected to each other to form an integral gate structure that surrounds the gate stack in the first direction (Z) and in a third direction (Y), which is perpendicular to the first and the second direction (Z, X).

4. The semiconductor structure according to claim 1, wherein:
-the filler material comprises undoped silicon, or doped silicon, or undoped silicon germanium, or doped silicon germanium, or a combination of both.

5. The semiconductor structure according to claim 1, wherein:
the first contact region and/or the second contact region comprises doped silicon or doped silicon germanium.

6. The semiconductor structure according to claim 1, wherein:
a doping concentration in the first contact region and/or in the second contact region is higher than in the filler material.

7. The semiconductor structure according to claim 1, wherein:
a first region of the gate stack in the first direction is a gate region, which is provided on the substrate, and a last region of the gate stack in the first direction (Z) is another gate region.

8. The semiconductor structure according to claim 1, wherein:
each gate region comprises a metallic region and a dielectric region which is configured to electrically isolate the metallic region from the channel regions adjacent to the gate region.

9. A method for fabricating a semiconductor structure, comprising:
forming an interim gate stack on a substrate of the semiconductor structure,
wherein the interim gate stack includes a plurality of sacrificial semiconductor regions and a plurality of silicon-based channel regions alternatingly arranged along a first direction (Z);
processing the sacrificial semiconductor regions so that a length of the sacrificial semiconductor regions (into a second direction (X) becomes smaller than a length of the silicon-based channel regions,
wherein a plurality of first pockets are formed on a first side of the interim gate stack, each first pocket is arranged next to one sacrificial semiconductor region and between the two channel regions adjacent to the sacrificial semiconductor-region,
depositing a filler material such that the filler material surrounds the processed interim gate stack and fills the first pockets;
forming a first contact region at a distance from the first side of the interim gate stack;
removing the sacrificial semiconductor regions; and
forming gate regions at locations where the sacrificial semiconductor regions were removed, to form a gate stack, wherein the gate stack is arranged on the substrate,
wherein a silicon-based first contact region extends along the first direction (Z) at a distance from a first side of the gate stack,
wherein a silicon-based filler material is arranged between the silicon-based first contact region and the first side of the gate stack and in each first pocket.
wherein the gate stack includes a plurality of gate regions and a plurality of silicon-based channel regions. which are alternatingly arranged along the first direction (Z).
wherein a length of the gate regions into the second direction (X), which is perpendicular to the first direction (Z), is smaller than a length of the silicon-based channel regions, and
wherein a plurality of first pockets are formed on the first side of the gate stack, and each first pocket is arranged next to one gate region and between two of the silicon-based channel regions adjacent to the gate region.

10. The method according to claim 9,
wherein the plurality of second pockets are formed on the second side of the interim gate stack, each second pocket being arranged next to one sacrificial semiconductor region and between the two channel regions adjacent to the sacrificial semiconductor region;
wherein the filler material fills the second pockets; and
the method further comprises, before removing the sacrificial semiconductor regions, forming the second contact region in the distance to the second side of the interim gate stack.

11. The method according to claim 10, wherein
the first contact region and the second contact region are formed simultaneously.

12. The method according to claim 9, wherein
the interim gate stack is formed by epitaxial growth on the substrate.

13. The method according to claim 9, further comprising:
after depositing the filler material,
forming a first trench and/or a second trench along the first direction (Z) into the filler material; and
forming the first contact region and/or the second contact region in, respectively, the first trench and/or the second trench.

14. The method according to claim 9, wherein
the processing of the sacrificial semiconductor regions further comprises: selective etching of a material of the sacrificial semiconductor regions;
and/or
wherein the removal of the sacrificial semiconductor regions comprises: selective etching of the material of the sacrificial semiconductor regions.

15. The method according to claim 9, wherein
the material of the sacrificial semiconductor regions comprises silicon germanium.
